(19) United States
(12) Patent Application Publication
(10) Pub. No.: US 2024/0028794 A1
(43) Pub. Date: Jan. 25, 2024

(54) EVENT PROCESSING AND PREDICTION UPDATING AT A DIGITAL TWIN

(71) Applicant: Accenture Global Solutions Limited, Dublin (IE)

(72) Inventors: Senthil Kumar KUMARESAN, Bangalore (IN); Nataraj KUNTAGOD, Bangalore (IN); Sanjay PODDER, Thane (IN); Venkatesh SUBRAMANIAN, Bangalore (IN); Suresh KUMAR MANI, Tamil Nadu (IN); Satya SAI SRINIVAS, Bangalore (IN); Kuntal DEY, Birbhum (IN)

(21) Appl. No.: 17/868,262

(22) Filed: Jul. 19, 2022

(51) Int. Cl. G06F 30/27

(52) U.S. Cl. CPC G06F 30/27

(57) ABSTRACT

In some implementations, a digital twin system may receive, from one or more sensors and at an interface associated with a digital twin, a first input associated with a first event. The digital twin system may determine that the first event is associated with one or more probable second events. Accordingly, the digital twin system may refrain from processing the first input for a period of time. The digital twin system may further update a prediction associated with the digital twin using the first input based on expiry of the period of time or may update a prediction associated with the digital twin using second input associated with the one or more probable second events based on receiving the second input.

### BACKGROUND

Computer simulation is often used to predict crop yields, manufacturing output, inventory movement, and other outputs. Computer simulation generally becomes more accurate with more inputs. Accordingly, accurate computer simulation usually consumes significant power and processing resources.

### SUMMARY

Some implementations described herein relate to a method. The method may include receiving, from one or more sensors and at an interface associated with a digital twin, a first input associated with a first event. The method may include determining that the first event is associated with one or more probable second events. The method may include refraining from processing the first input for a period of time. The method may include updating a prediction associated with the digital twin using the first input based on expiry of the period of time, or updating a prediction associated with the digital twin using second input associated with the one or more probable second events based on receiving the second input.

Some implementations described herein relate to a device. The device may include one or more memories and one or more processors communicatively coupled to the one or more memories. The one or more processors may be configured to receive, from one or more sensors and at an interface associated with a digital twin, input associated with a new event. The one or more processors may be configured to determine that the event triggers an update for a prediction associated with the digital twin. The one or more processors may be configured to select a model, from a plurality of possible models, based on a context associated with a current state of the digital twin or a context associated with the event. The one or more processors may be configured to update the prediction associated with the digital twin based on the selected model and the input.

Some implementations described herein relate to a non-transitory computer-readable medium that stores a set of instructions for a device. The set of instructions, when executed by one or more processors of the device, may cause the device to receive, from one or more sensors and at an interface associated with a digital twin, a first input associated with a first event. The set of instructions, when executed by one or more processors of the device, may cause the device to determine that the first event is associated with a probable second event. The set of instructions, when executed by one or more processors of the device, may cause the device to refrain from processing the first input for a period of time. The set of instructions, when executed by one or more processors of the device, may cause the device to receive a second input associated with the probable second event. The set of instructions, when executed by one or more processors of the device, may cause the device to select a model, from a plurality of possible models, based on a context associated with a current state of the digital twin or a context associated with the probable second event. The set of instructions, when executed by one or more processors of the device, may cause the device to update a prediction associated with the digital twin based on the selected model and the second input.

### BRIEF DESCRIPTION OF THE DRAWINGS

FIGS. 1A-1E are diagrams of an example implementation described herein.

FIG. 2 is a diagram of an example event hierarchy.

FIG. 3 is a diagram of an example cost function for a digital twin.

FIGS. 4A-4B are a diagram illustrating an example of training and using a machine learning model in connection with model selection at a digital twin.

FIG. 5 is a diagram of an example environment in which systems and/or methods described herein may be implemented.

FIG. 6 is a diagram of example components of one or more devices of FIG. 5.

FIG. 7 is a flowchart of an example process associated with event processing and prediction updating at a digital twin.

### DETAILED DESCRIPTION

The following detailed description of example implementations refers to the accompanying drawings. The same reference numbers in different drawings may identify the same or similar elements.

Digital twins of real-world objects may be used to simulate outputs from those objects. Accordingly, a digital twin may receive input based on signals from sensors like temperature sensors, pressure sensors, or optical sensors, among other examples. Additionally, or alternatively, the digital twin may receive information from third-party sources like remote servers. Input may be associated with an event (e.g., an unexpected weather event, a machine malfunction, or a labor strike, among other examples) that triggers an update to a prediction (e.g., an output volume, an output timeline, or a desired input level, among other examples) associated with the digital twin. Each update to the prediction consumes power and processing resources.

By filtering events and performing updates using less-accurate models, power and processing resources are conserved. Accordingly, some implementations described herein enable a digital twin host to refrain from processing input associated with a new event when the new event is associated with probable, subsequent events. As a result, the digital twin host conserves power and processing resources. Further, the digital twin host may update a prediction using input associated with a probable, subsequent event and ignoring the input associated with the original new event in order to further conserve power and processing resources. Additionally, or alternatively, some implementations described herein enable a digital twin host to use context associated with a new event and/or context associated with a current state of the digital twin. As a result, the digital twin host may select models that conserve power and processing resources in response to some types of events and may select models that increase accuracy in response to other types of events.

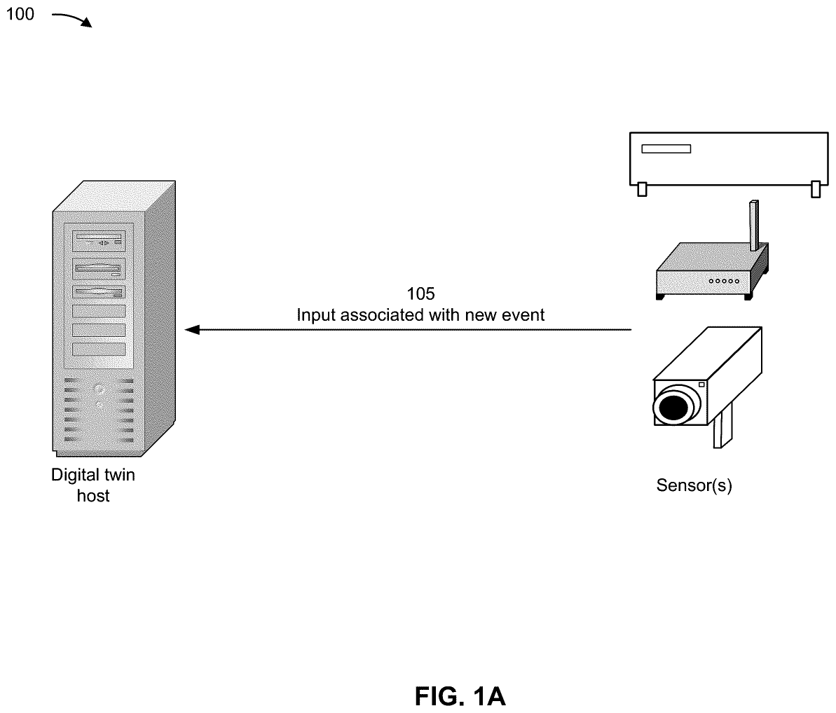

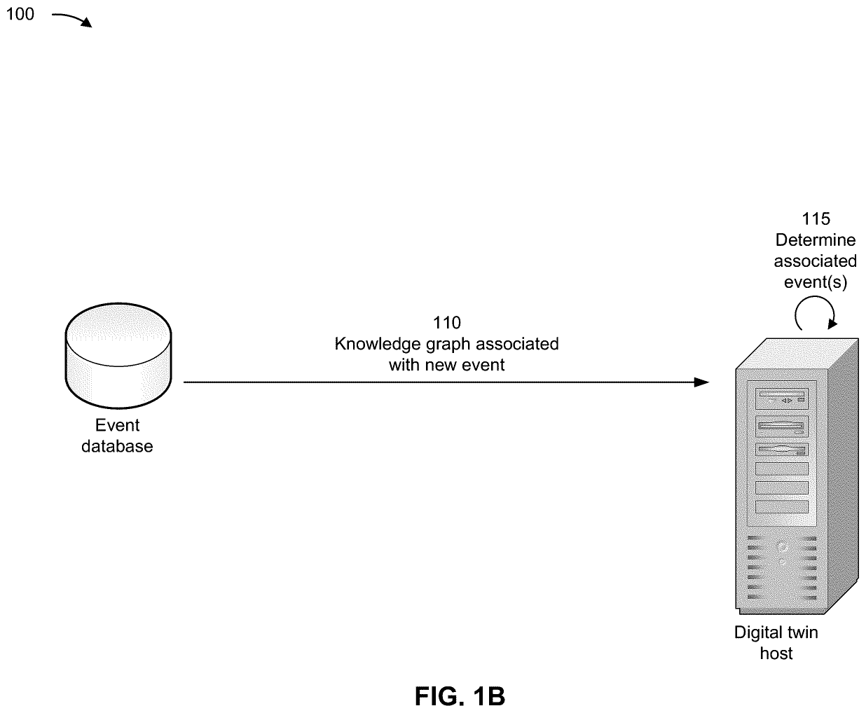

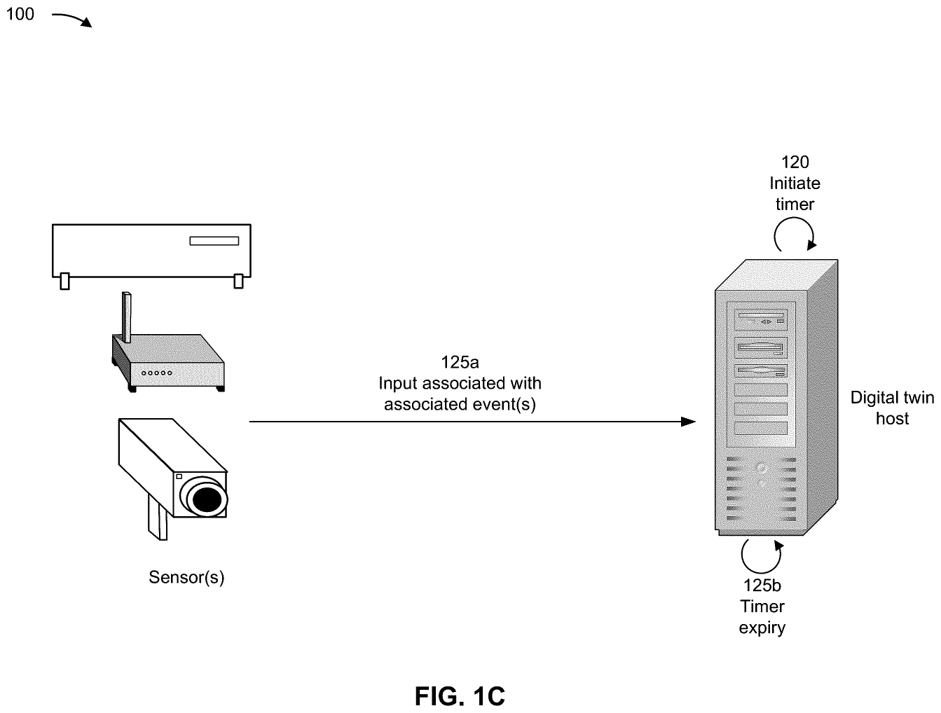

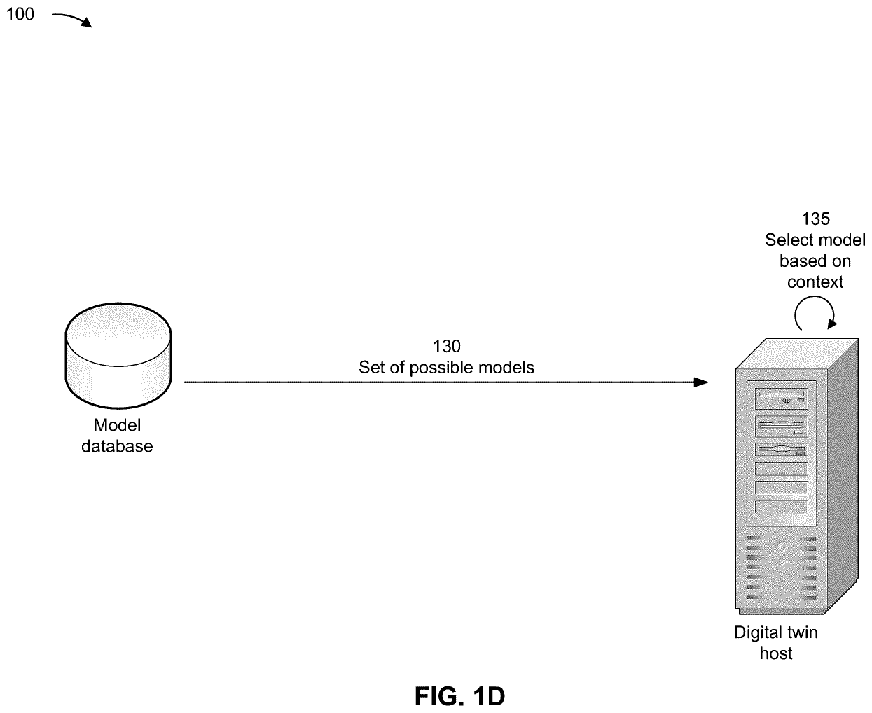

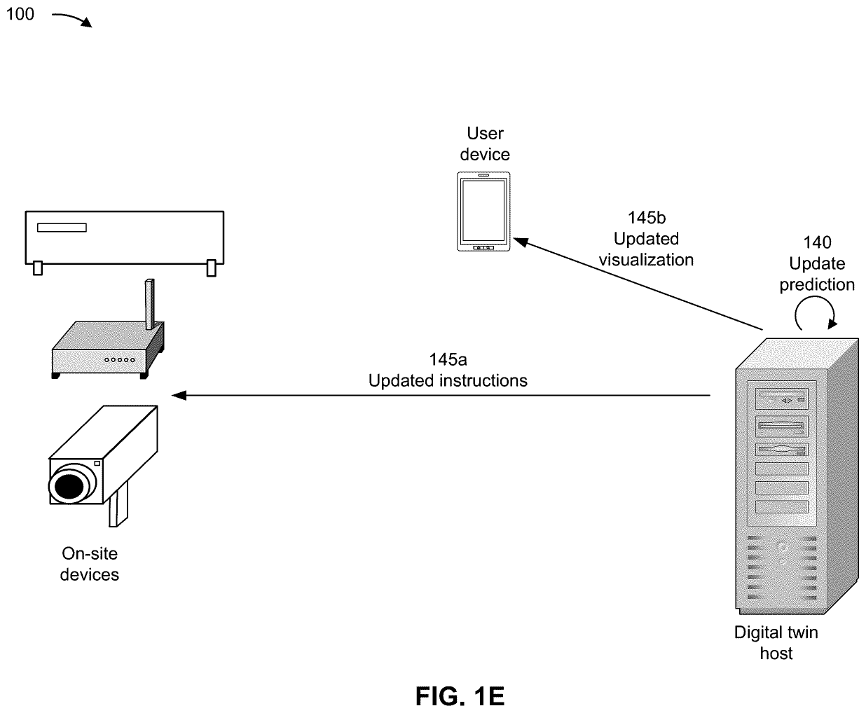

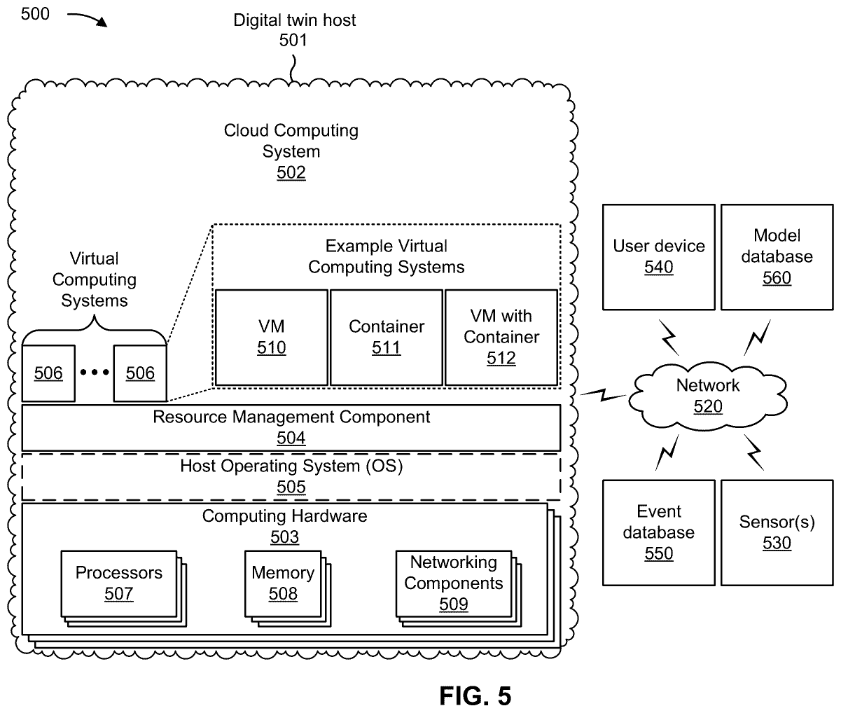

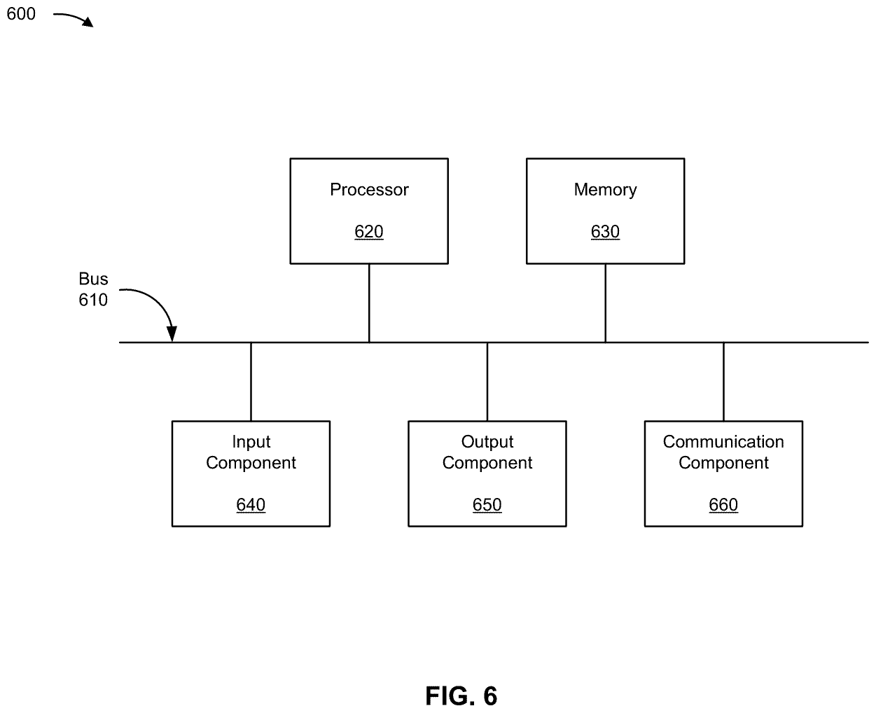

FIGS. 1A-1E are diagrams of an example implementation 100 associated with event processing and prediction updating at a digital twin. As shown in FIGS. 1A-1E, example implementation 100 includes a digital twin host, one or more sensors, an event database, a model database, and a user device. These devices are described in more detail below in connection with FIG. 5 and FIG. 6.

As shown by reference number 105, the sensor(s) may transmit, and the digital twin host may receive, a first input associated with a first event. The first input may comprise measurements (e.g., one or more measurements) that satisfy thresholds (e.g., one or more thresholds) associated with an event. For example, temperature, humidity, and/or pressure measurements that satisfy thresholds associated with a thunderstorm event may be transmitted to the digital twin host. In another example, images from an optical sensor may be analyzed (e.g., at the optical sensor and/or at the digital twin host) to identify a crop blight event.

Additionally, or alternatively, the first input may comprise signals from machines (e.g., one or more machines), such as manufacturing machines when the digital twin represents a factory or farming equipment when the digital twin represents a farm, among other examples. Additionally, or alternatively, the first input may comprise information from a third-party source (e.g., a remote server, such as device 600 of FIG. 6, which may include a standalone server or another type of computing device). For example, the third-party source may transmit an indication of a weather update or an electricity price update, among other examples.

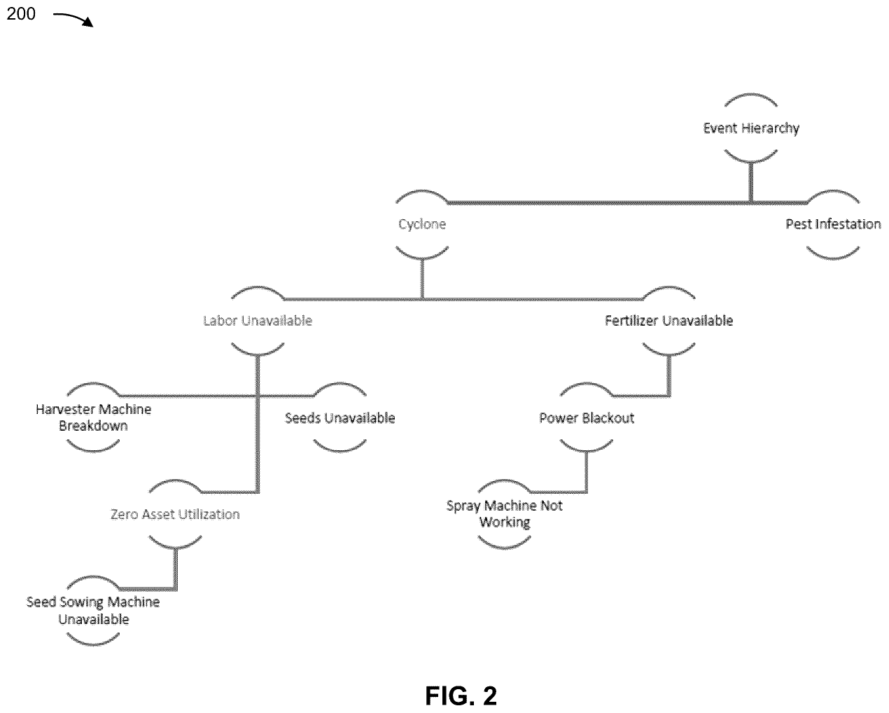

Accordingly, as shown in FIG. 1B and by reference number 110, the event database may transmit, and the digital twin host may receive, a knowledge graph associated with the first event. For example, the knowledge graph may include a hierarchy of event types, as described in connection with FIG. 2, and/or another type of data structure that indicates relationships between different types of events. In some implementations, the event database may be at least partially integrated with the digital twin host such that the digital twin host obtains the knowledge graph by retrieving a file (e.g., one or more files) from the event database or performing a similar function. Alternatively, the event database may be at least partially separate (e.g., physically, logically, and/or virtually) from the digital twin host such that the digital twin host retrieves the knowledge graph by transmitting a network request (e.g., a hypertext transfer protocol (HTTP) request, a file transfer protocol (FTP) request, or an application programming interface (API) call, among other examples) or performing a similar function.

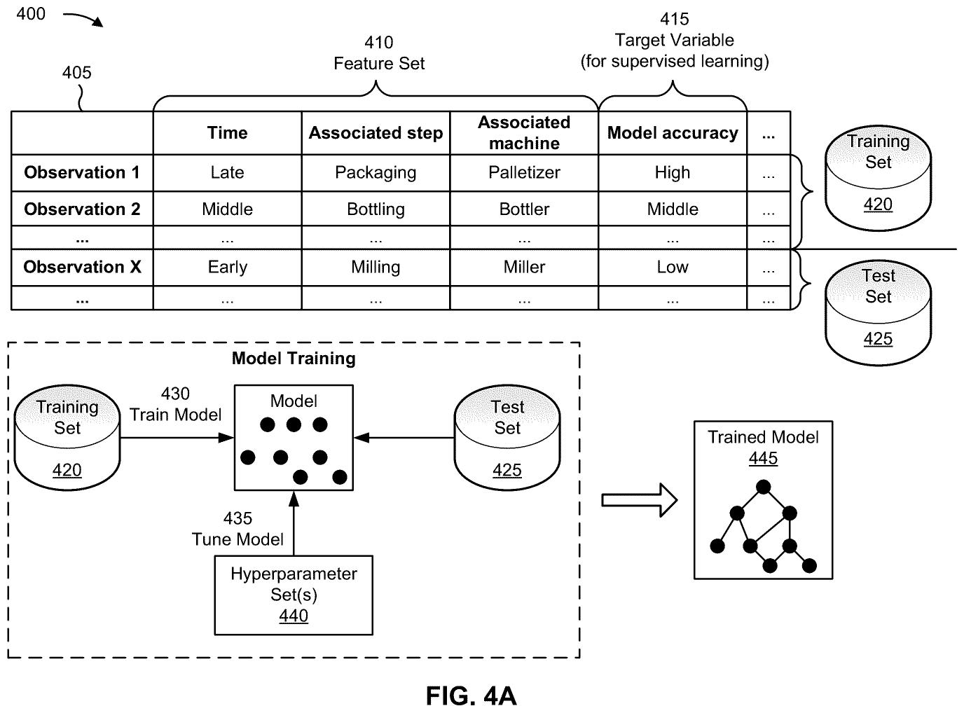

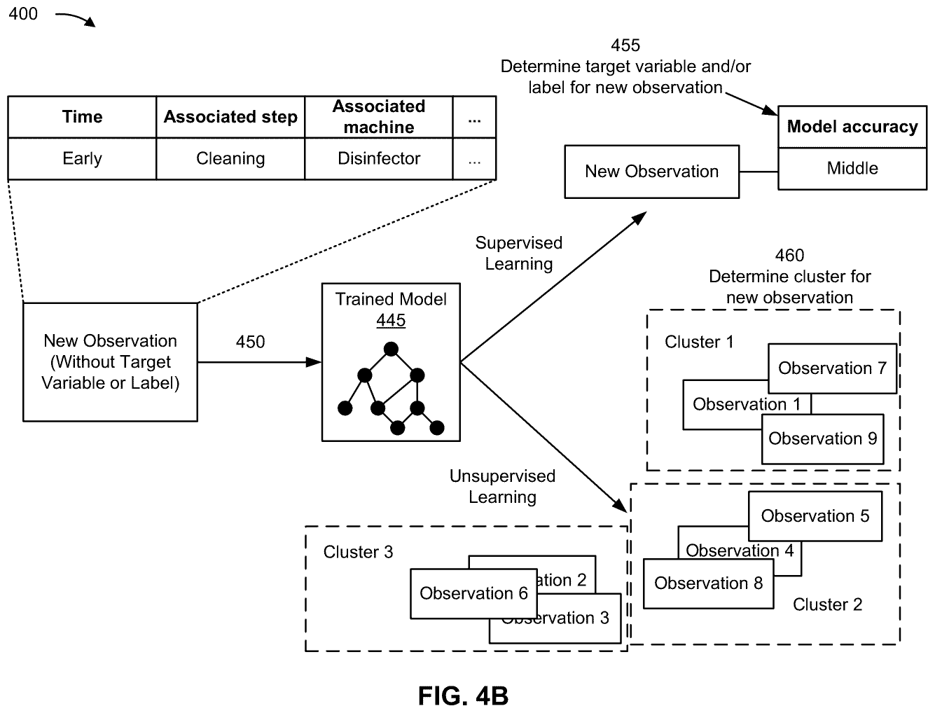

Therefore, as shown by reference number 115, the digital twin host may determine that the first event is associated with a probable second event (e.g., one or more probable second events). In some implementations, as described in connection with FIG. 2, the digital twin host may determine the probable second event as a higher-layer event within an event hierarchy. Additionally, or alternatively, the digital twin host may determine the probable second event based on an edge between a node representing the second event and a node representing the first event. Additionally, or alternatively, the digital twin host may apply a machine learning model (e.g., similar to the model described in connection with FIGS. 4A-4B) that outputs an indication of the probable second event in response to input that comprises an indication of the first event and/or the first input.

As shown in FIG. 1C, the digital twin host may refrain from processing the first input for a period of time. For example, as shown by reference number 120, the digital twin host may initiate a timer that tracks passage of the period of time. In some implementations, the period of time may be indicated by the data structure that indicates relationships between different types of events. For example, the period of time may be indicated in the event hierarchy, indicated in an edge of a graph database, or output by a machine learning model, among other examples. Alternatively, the digital twin host may apply a default period of time. Accordingly, the digital twin host conserves power and processing resources by refraining from processing the first input. Although the digital twin host refrains from updating a prediction based on the first input, the digital twin host may still update state variables and/or other properties associated with the digital twin based on the first input.

Accordingly, as shown by reference number 125a, the sensor(s) may transmit, and the digital twin host may receive, a second input associated with the probable second event. Additionally, or alternatively, similar to the first input, the second input may comprise signals from machines and/or information from a third-party source. Therefore, the digital twin host may proceed to process the second input as described in connection with FIGS. 1D and 1E. In some implementations, the digital twin host may further filter the first input in order to generate an updated prediction based on the second input. For example, because the second event is likely to have a larger effect on the prediction than the first event (e.g., based on the event hierarchy or another data structure that indicates relationships between different types of events), the digital twin host may conserve power and processing resources by ignoring the first input and processing only the second input.

Alternatively, as shown by reference number 125b, the digital twin host may detect expiry of the timer. Accordingly, the digital twin host may proceed to process the first input as described in connection with FIGS. 1D and 1E.

As shown in FIG. 1D and by reference number 130, the model database may transmit, and the digital twin host may receive, a set of possible models to apply. For example, the set of possible models may include a list, an array, and/or another type of data structure that indicates the set of possible models. In some implementations, the model database may be at least partially integrated with the digital twin host such that the digital twin host obtains the set of possible models by retrieving a file (e.g., one or more files) from the model database or performing a similar function. Alternatively, the model database may be at least partially separate (e.g., physically, logically, and/or virtually) from the digital twin host such that the digital twin host retrieves the set of possible models by transmitting a network request (e.g., an HTTP request, an FTP request, or an API call, among other examples) or performing a similar function.

Therefore, as shown by reference number 135, the digital twin host may select a model, from the set of possible models, based on a context associated with a current state of the digital twin and/or a context associated with the event being processed (e.g., the first event and/or the probable second event, as described above). Examples of the context associated with the current state of the digital twin include a location associated with the digital twin, a time associated with the digital twin, or a current function associated with the digital twin. For example, the digital twin host may select a model with greater accuracy when the digital twin is located within a supply chain whose size satisfies a size threshold but may select a model that conserves power and processing resources when the digital twin is located within a supply chain whose size fails to satisfy the size threshold. In another example, the digital twin host may select a model with greater accuracy when the digital twin is within a harvest season or processing an order that satisfies an order threshold, among other examples, but may select a model that conserves power and processing resources when the digital twin is outside a harvest season or processing an order that fails to satisfy the order threshold, among other examples. In another example, the digital twin host may select a model with greater accuracy when the digital twin is performing harvesting or performing packaging, among other examples, but may select a model that conserves power and processing resources when the digital twin is performing fertilization or performing inventory, among other examples.

Examples of the context associated with the event include a location associated with the event, a time associated with the event, or a current function associated with the event. For example, the digital twin host may select a model with greater accuracy when the event satisfies a distance threshold relative to a center a farm represented by the digital twin or is located in one or more critical areas of a factory represented by the digital twin, among other examples, but may select a model that conserves power and processing resources when the event fails to satisfy the distance threshold relative to a center a farm represented by the digital twin or is located in one or more non-critical areas of a factory represented by the digital twin, among other examples. In another example, the digital twin host may select a model with greater accuracy when the event occurs during a harvest season or during processing of an order that satisfies an order threshold, among other examples, but may select a model that conserves power and processing resources when the event occurs outside a harvest season or during processing of an order that fails to satisfy the order threshold, among other examples. In another example, the digital twin host may select a model with greater accuracy when the event is associated with a harvester or a packager, among other examples, but may select a model that conserves power and processing resources when the event is associated with a fertilizer or a forklift, among other examples.

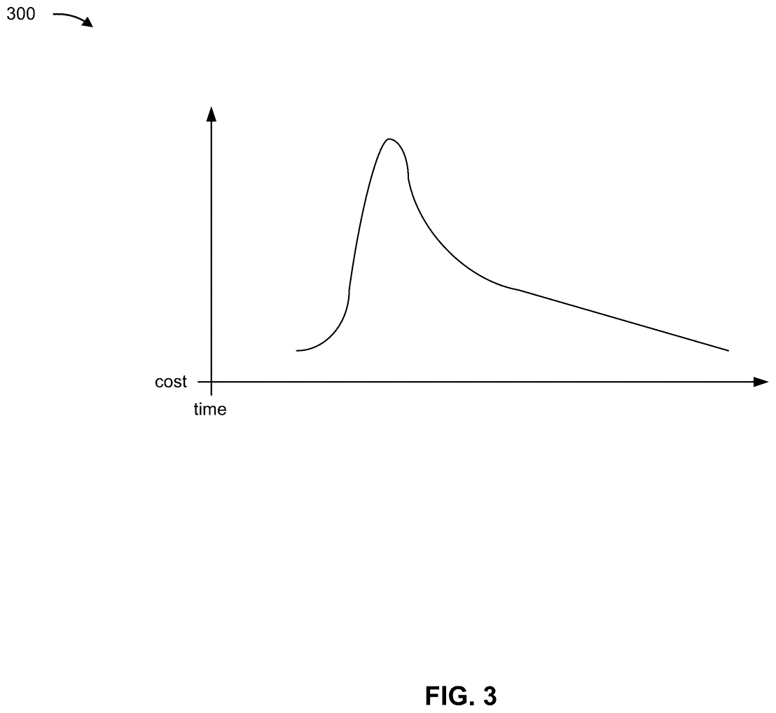

In some implementations, as described in connection with FIG. 3, the digital twin host may calculate a corresponding cost and a corresponding error (or a corresponding accuracy) for each model of the plurality of possible models. Thus, the digital twin host may select the model based on the corresponding cost and the corresponding error for the model. For example, the digital twin host may select a model that satisfies a cost threshold and/or an accuracy threshold determined based on a cost function and contextual information (e.g., as described above).

Additionally, or alternatively, the digital twin host may apply a machine learning model, as described in connection with FIGS. 4A-4B, to select the model. For example, the digital twin host may include contextual information (e.g., as described above) into the machine learning model and receive, as output, a recommended model (or models) to use. When the machine learning model recommends two or more models, the digital twin host may select based on a lower cost or a higher accuracy between the recommended models.

In some implementations, the digital twin host may receive additional inputs (e.g., one or more additional inputs) based on the selected model. For example, the model may accept weather information and/or machine status information, among other examples, as input. Accordingly, the digital twin host may request the additional inputs from a third-party source (e.g., one or more third-party sources). For example, the digital twin host may retrieve the additional inputs by transmitting a network request (e.g., an HTTP request, an FTP request, or an API call, among other examples) or performing a similar function.

As shown in FIG. 1E and by reference number 140, the digital twin host may update a prediction associated with the digital twin based on the selected model and the input associated with the event being processed (e.g., the first event and/or the probable second event, as described above). For example, the digital twin host may execute the selected model using the input (optionally with the additional inputs, as described above) to generate an updated prediction. The prediction may include an input prediction (e.g., an amount of water, electricity, natural gas, or other utilities to use; a quantity of seeds for a farm; or a quantity of raw materials for a factory) or an output prediction (e.g., an expected quantity of crops or an expected quantity of fabricated goods).

Accordingly, as shown by reference number 145a, the digital twin host may transmit, and the sensor(s) may receive, updated instructions for monitoring. For example, the updated prediction may include a smaller expected quantity of crops such that the digital twin host disables sensors associated with a portion of a farm expected to lie fallow. In another example, the updated prediction may include a smaller expected quantity of fabricated goods such that the digital twin host disables sensors associated with a loading dock that will not be used. In another example, the updated prediction may include a larger quantity of seeds such that the digital twin host enables additional sensors associated with planters and fertilizers that will now be used. In another example, the updated prediction may include a larger quantity of raw materials such that the digital twin host enables additional sensors associated with loading docks that will now be used.

Additionally, or alternatively, the digital twin host may update other digital twins that are related to the digital twin associated with the updated prediction. For example, the digital twin host may transmit an indication of the updated prediction to additional digital twin hosts (e.g., one or more additional digital twin hosts). Accordingly, the other digital twins may be updated to account for extra output, reduced output, extra input, or reduced input associated with the digital twin. If the digital twin host also hosts related digital twins (e.g., one or more related digital twins), the digital twin host may update the related digital twins automatically.

Additionally, or alternatively, as shown by reference number 145b, the digital twin host may transmit, and the user device may receive, a visualization associated with the updated prediction. For example, the digital twin host may output a text indication of the updated prediction for display. Additionally, or alternatively, the digital twin host may output an update to a graph displaying the prediction such that graph is updated to display the updated prediction. In some implementations, the graph may further illustrate the change from the prediction to the updated prediction.

In some implementations, the digital twin host may process input associated with an event, as described in connection with FIGS. 1D and 1E, without waiting for an associated event as described in connection with FIGS. 1B and 1C. For example, the event may not have associated events (e.g., the event is a top layer event in an event hierarchy, the event's edges indicate no associated events, or a machine learning model predicts no associated events, among other examples). Alternatively, the digital twin host may determine to process all events immediately (e.g., based on a context associated with a current state of the digital twin). For example, during a harvest season, the digital twin host may determine to process all events immediately for digital twins representing farms. In another example, the digital twin host may determine to process all events immediately for a digital twin representing a factory during a period of time before a ship, a lorry, or another transport vehicle is expected to arrive at the factory.

Alternatively, the digital twin host may refrain from processing input associated with an event, as described in connection with FIGS. 1B and 1C, without subsequently performing model selection as described in connection with FIGS. 1D and 1E. For example, the digital twin may only be associated with a single model to apply. Alternatively, the digital twin host may determine to use a particular model regardless of input (e.g., based on a context associated with a current state of the digital twin). For example, during a harvest season, the digital twin host may determine to use a high-accuracy model for all events. In another example, the digital twin host may determine to use a high-accuracy model for all events for a digital twin representing a factory during a period of time before a ship, a lorry, or another transport vehicle is expected to arrive at the factory.

As indicated above, FIGS. 1A-1E are provided as an example. Other examples may differ from what is described with regard to FIGS. 1A-1E. The number and arrangement of devices shown in FIGS. 1A-1E are provided as an example. In practice, there may be additional devices, fewer devices, different devices, or differently arranged devices than those shown in FIGS. 1A-1E. Furthermore, two or more devices shown in FIGS. 1A-1E may be implemented within a single device, or a single device shown in FIGS. 1A-1E may be implemented as multiple, distributed devices. Additionally, or alternatively, a set of devices (e.g., one or more devices) shown in FIGS. 1A-1E may perform one or more functions described as being performed by another set of devices shown in FIGS. 1A-1E.

FIG. 2 is a diagram of an example event hierarchy 200 for a digital twin. Example event hierarchy 200 may be stored on an event database and used by a digital twin host. These devices are described in more detail below in connection with FIG. 5 and FIG. 6.

As shown in FIG. 2, an event hierarchy may rank a plurality of events. For example, a top layer of events for a digital twin representing a farm includes “Cyclone” and “Pest Infestation,” and a second layer of events includes “Labor Unavailable” and “Fertilizer Unavailable.” Further, a third layer of events includes “Harvester Machine Breakdown,” “Seeds Unavailable,” and “Power Blackout,” a fourth layer of events includes “Zero Asset Utilization” and “Spray Machine Not Working,” and a bottom layer of events includes “Seed Sowing Machine Unavailable.”

Furthermore, the layers of events are connected (e.g., by a weight, a probability, or another type of connecting value). Therefore, the digital twin host may determine when higher-layer events are probable to follow a lower-layer event. For example, using the example event hierarchy 200, the digital twin host may refrain from processing a “Zero Asset Utilization” event because a “Labor Unavailable” event is a probable subsequent event. Similarly, using the example event hierarchy 200, the digital twin host may refrain from processing a “Spray Machine Not Working” event because a “Power Blackout” event is a probable subsequent event. Although not shown in FIG. 2, an event hierarchy may further indicate an amount of time within which the probable subsequent event is expected. Accordingly, the digital twin host may proceed with processing the lower-layer event when the amount of time has passed without the probably subsequent event occurring.

As indicated above, FIG. 2 is provided as an example. Other examples may differ from what is described with regard to FIG. 2.

FIG. 3 is a diagram of an example cost function 300 for a digital twin. Example cost function 300 may be stored using a model database and used by a digital twin host. These devices are described in more detail below in connection with FIG. 5 and FIG. 6.

Example cost function 300 expresses a cost threshold (e.g., in power, processing resources, and/or another computational cost) relative to a time associated with a current state of the digital twin. Other examples may use different contextual variables, such as a time associated with an event, a location associated with the event, or a machine associated with the event, among other examples, as described herein.

Accordingly, based on the example cost function 300, the digital twin host may select a model, from a plurality of possible models, associated with a cost that satisfies the cost threshold but also provides maximum accuracy. Additionally, or alternatively, the digital twin host may use a function that expresses an accuracy threshold relative to a contextual variable and thus select a model, from a plurality of possible models, associated with an accuracy that satisfies the accuracy threshold but also provides minimum cost.

As indicated above, FIG. 3 is provided as an example. Other examples may differ from what is described with regard to FIG. 3.

FIG. 4A is a diagram illustrating an example 400 of training and using a machine learning model in connection with model selection at a digital twin. The machine learning model training described herein may be performed using a machine learning system. The machine learning system may include or may be included in a computing device, a server, a cloud computing environment, or the like, such as a digital twin host described in more detail below.

As shown by reference number 405, a machine learning model may be trained using a set of observations. The set of observations may be obtained and/or input from training data (e.g., historical data), such as data gathered during one or more processes described herein. For example, the set of observations may include data gathered from a model database, as described elsewhere herein. In some implementations, the machine learning system may receive the set of observations (e.g., as input) from the digital twin host.

As shown by reference number 410, a feature set may be derived from the set of observations. The feature set may include a set of variables. A variable may be referred to as a feature. A specific observation may include a set of variable values corresponding to the set of variables. A set of variable values may be specific to an observation. In some cases, different observations may be associated with different sets of variable values, sometimes referred to as feature values. In some implementations, the machine learning system may determine variables for a set of observations and/or variable values for a specific observation based on input received from the model database. For example, the machine learning system may identify a feature set (e.g., one or more features and/or corresponding feature values) from structured data input to the machine learning system, such as by extracting data from a particular column of a table, extracting data from a particular field of a form and/or a message, and/or extracting data received in a structured data format. Additionally, or alternatively, the machine learning system may receive input from an operator to determine features and/or feature values. In some implementations, the machine learning system may perform natural language processing and/or another feature identification technique to extract features (e.g., variables) and/or feature values (e.g., variable values) from text (e.g., unstructured data) input to the machine learning system, such as by identifying keywords and/or values associated with those keywords from the text.

As an example, a feature set for a set of observations may include a first feature of a time associated with an event, a second feature of a processing step associated with the event, a third feature of a machine associated with the event, and so on. As shown, for a first observation, the first feature may have a value of “early” (e.g., relative to a processing flow performed by the digital twin), the second feature may have a value of “packaging,” the third feature may have a value of “palletizer,” and so on. These features and feature values are provided as examples, and may differ in other examples. For example, the feature set may include one or more of the following features: a type or other classification of the event, an identifier of a building associated with the event, a type of input associated with the event, or a type of output associated with the event, among other examples. Additionally, or alternatively, the time may be measured numerically (e.g., in coordinated universal time (UTC)) rather than qualitatively. In some implementations, the machine learning system may pre-process and/or perform dimensionality reduction to reduce the feature set and/or combine features of the feature set to a minimum feature set. A machine learning model may be trained on the minimum feature set, thereby conserving resources of the machine learning system (e.g., processing resources and/or memory resources) used to train the machine learning model.

As shown by reference number 415, the set of observations may be associated with a target variable. The target variable may represent a variable having a numeric value (e.g., an integer value or a floating point value), may represent a variable having a numeric value that falls within a range of values or has some discrete possible values, may represent a variable that is selectable from one of multiple options (e.g., one of multiples classes, classifications, or labels), or may represent a variable having a Boolean value (e.g., 0 or 1, True or False, Yes or No), among other examples. A target variable may be associated with a target variable value, and a target variable value may be specific to an observation. In some cases, different observations may be associated with different target variable values. In example 400, the target variable is a model accuracy to select, which has a value of “middle” for the first observation. In other example, the accuracy may be measured numerically (e.g., by percentage) rather than qualitatively.

The target variable may represent a value that a machine learning model is being trained to predict, and the feature set may represent the variables that are input to a trained machine learning model to predict a value for the target variable. The set of observations may include target variable values so that the machine learning model can be trained to recognize patterns in the feature set that lead to a target variable value. A machine learning model that is trained to predict a target variable value may be referred to as a supervised learning model or a predictive model. When the target variable is associated with continuous target variable values (e.g., a range of numbers), the machine learning model may employ a regression technique. When the target variable is associated with categorical target variable values (e.g., classes or labels), the machine learning model may employ a classification technique.

In some implementations, the machine learning model may be trained on a set of observations that do not include a target variable (or that include a target variable, but the machine learning model is not being executed to predict the target variable). This may be referred to as an unsupervised learning model, an automated data analysis model, or an automated signal extraction model. In this case, the machine learning model may learn patterns from the set of observations without labeling or supervision, and may provide output that indicates such patterns, such as by using clustering and/or association to identify related groups of items within the set of observations.

As further shown, the machine learning system may partition the set of observations into a training set 420 that includes a first subset of observations, of the set of observations, and a test set 425 that includes a second subset of observations of the set of observations. The training set 420 may be used to train (e.g., fit or tune) the machine learning model, while the test set 425 may be used to evaluate a machine learning model that is trained using the training set 420. For example, for supervised learning, the test set 425 may be used for initial model training using the first subset of observations, and the test set 425 may be used to test whether the trained model accurately predicts target variables in the second subset of observations. In some implementations, the machine learning system may partition the set of observations into the training set 420 and the test set 425 by including a first portion or a first percentage of the set of observations in the training set 420 (e.g., 75%, 80%, or 85%, among other examples) and including a second portion or a second percentage of the set of observations in the test set 425 (e.g., 25%, 20%, or 15%, among other examples). In some implementations, the machine learning system may randomly select observations to be included in the training set 420 and/or the test set 425.

As shown by reference number 430, the machine learning system may train a machine learning model using the training set 420. This training may include executing, by the machine learning system, a machine learning algorithm to determine a set of model parameters based on the training set 420. In some implementations, the machine learning algorithm may include a regression algorithm (e.g., linear regression or logistic regression), which may include a regularized regression algorithm (e.g., Lasso regression, Ridge regression, or Elastic-Net regression). Additionally, or alternatively, the machine learning algorithm may include a decision tree algorithm, which may include a tree ensemble algorithm (e.g., generated using bagging and/or boosting), a random forest algorithm, or a boosted trees algorithm. A model parameter may include an attribute of a machine learning model that is learned from data input into the model (e.g., the training set 420). For example, for a regression algorithm, a model parameter may include a regression coefficient (e.g., a weight). For a decision tree algorithm, a model parameter may include a decision tree split location, as an example.

As shown by reference number 435, the machine learning system may use one or more hyperparameter sets 440 to tune the machine learning model. A hyperparameter may include a structural parameter that controls execution of a machine learning algorithm by the machine learning system, such as a constraint applied to the machine learning algorithm. Unlike a model parameter, a hyperparameter is not learned from data input into the model. An example hyperparameter for a regularized regression algorithm includes a strength (e.g., a weight) of a penalty applied to a regression coefficient to mitigate overfitting of the machine learning model to the training set 420. The penalty may be applied based on a size of a coefficient value (e.g., for Lasso regression, such as to penalize large coefficient values), may be applied based on a squared size of a coefficient value (e.g., for Ridge regression, such as to penalize large squared coefficient values), may be applied based on a ratio of the size and the squared size (e.g., for Elastic-Net regression), and/or may be applied by setting one or more feature values to zero (e.g., for automatic feature selection). Example hyperparameters for a decision tree algorithm include a tree ensemble technique to be applied (e.g., bagging, boosting, a random forest algorithm, and/or a boosted trees algorithm), a number of features to evaluate, a number of observations to use, a maximum depth of each decision tree (e.g., a number of branches permitted for the decision tree), or a number of decision trees to include in a random forest algorithm.

To train a machine learning model, the machine learning system may identify a set of machine learning algorithms to be trained (e.g., based on operator input that identifies the one or more machine learning algorithms and/or based on random selection of a set of machine learning algorithms), and may train the set of machine learning algorithms (e.g., independently for each machine learning algorithm in the set) using the training set 420. The machine learning system may tune each machine learning algorithm using one or more hyperparameter sets 440 (e.g., based on operator input that identifies hyperparameter sets 440 to be used and/or based on randomly generating hyperparameter values). The machine learning system may train a particular machine learning model using a specific machine learning algorithm and a corresponding hyperparameter set 440. In some implementations, the machine learning system may train multiple machine learning models to generate a set of model parameters for each machine learning model, where each machine learning model corresponds to a different combination of a machine learning algorithm and a hyperparameter set 440 for that machine learning algorithm.

In some implementations, the machine learning system may perform cross-validation when training a machine learning model. Cross validation can be used to obtain a reliable estimate of machine learning model performance using only the training set 420, and without using the test set 425, such as by splitting the training set 420 into a number of groups (e.g., based on operator input that identifies the number of groups and/or based on randomly selecting a number of groups) and using those groups to estimate model performance. For example, using k-fold cross-validation, observations in the training set 420 may be split into k groups (e.g., in order or at random). For a training procedure, one group may be marked as a hold-out group, and the remaining groups may be marked as training groups. For the training procedure, the machine learning system may train a machine learning model on the training groups and then test the machine learning model on the hold-out group to generate a cross-validation score. The machine learning system may repeat this training procedure using different hold-out groups and different test groups to generate a cross-validation score for each training procedure. In some implementations, the machine learning system may independently train the machine learning model k times, with each individual group being used as a hold-out group once and being used as a training group k−1 times. The machine learning system may combine the cross-validation scores for each training procedure to generate an overall cross-validation score for the machine learning model. The overall cross-validation score may include, for example, an average cross-validation score (e.g., across all training procedures), a standard deviation across cross-validation scores, or a standard error across cross-validation scores.

In some implementations, the machine learning system may perform cross-validation when training a machine learning model by splitting the training set into a number of groups (e.g., based on operator input that identifies the number of groups and/or based on randomly selecting a number of groups). The machine learning system may perform multiple training procedures and may generate a cross-validation score for each training procedure. The machine learning system may generate an overall cross-validation score for each hyperparameter set 440 associated with a particular machine learning algorithm. The machine learning system may compare the overall cross-validation scores for different hyperparameter sets 440 associated with the particular machine learning algorithm, and may select the hyperparameter set 440 with the best (e.g., highest accuracy, lowest error, or closest to a desired threshold) overall cross-validation score for training the machine learning model. The machine learning system may then train the machine learning model using the selected hyperparameter set 440, without cross-validation (e.g., using all of data in the training set 420 without any hold-out groups), to generate a single machine learning model for a particular machine learning algorithm. The machine learning system may then test this machine learning model using the test set 425 to generate a performance score, such as a mean squared error (e.g., for regression), a mean absolute error (e.g., for regression), or an area under receiver operating characteristic curve (e.g., for classification). If the machine learning model performs adequately (e.g., with a performance score that satisfies a threshold), then the machine learning system may store that machine learning model as a trained machine learning model 445 to be used to analyze new observations, as described below in connection with FIG. 4B.

In some implementations, the machine learning system may perform cross-validation, as described above, for multiple machine learning algorithms (e.g., independently), such as a regularized regression algorithm, different types of regularized regression algorithms, a decision tree algorithm, or different types of decision tree algorithms. Based on performing cross-validation for multiple machine learning algorithms, the machine learning system may generate multiple machine learning models, where each machine learning model has the best overall cross-validation score for a corresponding machine learning algorithm. The machine learning system may then train each machine learning model using the entire training set 420 (e.g., without cross-validation), and may test each machine learning model using the test set 425 to generate a corresponding performance score for each machine learning model. The machine learning model may compare the performance scores for each machine learning model, and may select the machine learning model with the best (e.g., highest accuracy, lowest error, or closest to a desired threshold) performance score as the trained machine learning model 445.

FIG. 4B is a diagram illustrating applying the trained machine learning model 445 to a new observation. As shown by reference number 450, the machine learning system may receive a new observation (or a set of new observations), and may input the new observation to the machine learning model 445. As shown, the new observation may include a first feature of “early,” a second feature of “cleaning,” a third feature of “disinfector,” and so on, as an example. The machine learning system may apply the trained machine learning model 445 to the new observation to generate an output (e.g., a result). The type of output may depend on the type of machine learning model and/or the type of machine learning task being performed. For example, the output may include a predicted (e.g., estimated) value of target variable (e.g., a value within a continuous range of values, a discrete value, a label, a class, or a classification), such as when supervised learning is employed. Additionally, or alternatively, the output may include information that identifies a cluster to which the new observation belongs and/or information that indicates a degree of similarity between the new observation and one or more prior observations (e.g., which may have previously been new observations input to the machine learning model and/or observations used to train the machine learning model), such as when unsupervised learning is employed.

In some implementations, the trained machine learning model 445 may predict a value of “middle” for the target variable of model accuracy for the new observation, as shown by reference number 455. Based on this prediction (e.g., based on the value having a particular label or classification or based on the value satisfying or failing to satisfy a threshold), the machine learning system may provide a recommendation and/or output for determination of a recommendation, such as a recommended model (or models) to apply. Additionally, or alternatively, the machine learning system may perform an automated action and/or may cause an automated action to be performed (e.g., by instructing another device to perform the automated action), such as initiating a recommended model for updating a prediction associated with a digital twin. As another example, if the machine learning system were to predict a value of “low” for the target variable of model accuracy, then the machine learning system may provide a different recommendation (e.g., a different recommended model (or models) to apply) and/or may perform or cause performance of a different automated action (e.g., initiating a different recommended model for updating the prediction associated with the digital twin). In some implementations, the recommendation and/or the automated action may be based on the target variable value having a particular label (e.g., classification or categorization) and/or may be based on whether the target variable value satisfies one or more threshold (e.g., whether the target variable value is greater than a threshold, is less than a threshold, is equal to a threshold, or falls within a range of threshold values).

In some implementations, the trained machine learning model 445 may classify (e.g., cluster) the new observation in a cluster, as shown by reference number 460. The observations within a cluster may have a threshold degree of similarity. As an example, if the machine learning system classifies the new observation in a first cluster (e.g., associated with high accuracy models), then the machine learning system may provide a first recommendation, such as a first set of recommended models to use. Additionally, or alternatively, the machine learning system may perform a first automated action and/or may cause a first automated action to be performed (e.g., by instructing another device to perform the automated action) based on classifying the new observation in the first cluster, such as initiating a first recommended model for updating a prediction associated with a digital twin. As another example, if the machine learning system were to classify the new observation in a second cluster (e.g., associated with low accuracy models), then the machine learning system may provide a second (e.g., different) recommendation (e.g., a second set of recommended models to use) and/or may perform or cause performance of a second (e.g., different) automated action, such as initiating a second recommended model for updating the prediction associated with the digital twin.

In this way, the machine learning system may apply a rigorous and automated process to model selection. For example, the machine learning system may apply contextual rules to select a model. Accordingly, the machine learning system enables recognition and/or identification of tens, hundreds, thousands, or millions of features and/or feature values for tens, hundreds, thousands, or millions of observations, thereby increasing accuracy and consistency and reducing delay associated with selecting models relative to requiring computing resources to be allocated for tens, hundreds, or thousands of operators to manually select models using the features or feature values. Accordingly, the machine learning system may quickly and accurately balance power and processing resource usage with prediction accuracy based on context associated with the event and/or context associated with the digital twin.

As indicated above, FIGS. 4A-4B are provided as an example. Other examples may differ from what is described in connection with FIGS. 4A-4B. For example, the machine learning model may be trained using a different process than what is described in connection with FIG. 4A. Additionally, or alternatively, the machine learning model may employ a different machine learning algorithm than what is described in connection with FIGS. 4A-4B, such as a Bayesian estimation algorithm, a k-nearest neighbor algorithm, an a priori algorithm, a k-means algorithm, a support vector machine algorithm, a neural network algorithm (e.g., a convolutional neural network algorithm), and/or a deep learning algorithm.

FIG. 5 is a diagram of an example environment 500 in which systems and/or methods described herein may be implemented. As shown in FIG. 5, environment 500 may include a digital twin host 501, which may include one or more elements of and/or may execute within a cloud computing system 502. The cloud computing system 502 may include one or more elements 503-512, as described in more detail below. As further shown in FIG. 5, environment 500 may include a network 520, one or more sensor(s) 530, a user device 540, an event database 550, and/or a model database 560. Devices and/or elements of environment 500 may interconnect via wired connections and/or wireless connections.

The cloud computing system 502 includes computing hardware 503, a resource management component 504, a host operating system (OS) 505, and/or one or more virtual computing systems 506. The cloud computing system 502 may execute on, for example, an Amazon Web Services platform, a Microsoft Azure platform, or a Snowflake platform. The resource management component 504 may perform virtualization (e.g., abstraction) of computing hardware 503 to create the one or more virtual computing systems 506. Using virtualization, the resource management component 504 enables a single computing device (e.g., a computer or a server) to operate like multiple computing devices, such as by creating multiple isolated virtual computing systems 506 from computing hardware 503 of the single computing device. In this way, computing hardware 503 can operate more efficiently, with lower power consumption, higher reliability, higher availability, higher utilization, greater flexibility, and lower cost than using separate computing devices.

Computing hardware 503 includes hardware and corresponding resources from one or more computing devices. For example, computing hardware 503 may include hardware from a single computing device (e.g., a single server) or from multiple computing devices (e.g., multiple servers), such as multiple computing devices in one or more data centers. As shown, computing hardware 503 may include one or more processors 507, one or more memories 508, and/or one or more networking components 509. Examples of a processor, a memory, and a networking component (e.g., a communication component) are described elsewhere herein.

The resource management component 504 includes a virtualization application (e.g., executing on hardware, such as computing hardware 503) capable of virtualizing computing hardware 503 to start, stop, and/or manage one or more virtual computing systems 506. For example, the resource management component 504 may include a hypervisor (e.g., a bare-metal or Type 1 hypervisor, a hosted or Type 2 hypervisor, or another type of hypervisor) or a virtual machine monitor, such as when the virtual computing systems 506 are virtual machines 510. Additionally, or alternatively, the resource management component 504 may include a container manager, such as when the virtual computing systems 506 are containers 511. In some implementations, the resource management component 504 executes within and/or in coordination with a host operating system 505.

A virtual computing system 506 includes a virtual environment that enables cloud-based execution of operations and/or processes described herein using computing hardware 503. As shown, a virtual computing system 506 may include a virtual machine 510, a container 511, or a hybrid environment 512 that includes a virtual machine and a container, among other examples. A virtual computing system 506 may execute one or more applications using a file system that includes binary files, software libraries, and/or other resources required to execute applications on a guest operating system (e.g., within the virtual computing system 506) or the host operating system 505.

Although the digital twin host 501 may include one or more elements 503-512 of the cloud computing system 502, may execute within the cloud computing system 502, and/or may be hosted within the cloud computing system 502, in some implementations, the digital twin host 501 may not be cloud-based (e.g., may be implemented outside of a cloud computing system) or may be partially cloud-based. For example, the digital twin host 501 may include one or more devices that are not part of the cloud computing system 502, such as device 600 of FIG. 6, which may include a standalone server or another type of computing device. The digital twin host 501 may perform one or more operations and/or processes described in more detail elsewhere herein.

Network 520 includes one or more wired and/or wireless networks. For example, network 520 may include a cellular network, a public land mobile network (PLMN), a local area network (LAN), a wide area network (WAN), a private network, the Internet, and/or a combination of these or other types of networks. The network 520 enables communication among the devices of environment 500.

The sensor(s) 530 include one or more devices capable of receiving, generating, storing, processing, and/or providing information associated with environment variables associated with a digital twin, as described elsewhere herein. The sensor(s) 530 may include temperature sensors, pressure sensors, humidity sensors, optical sensors, or other similar types of sensors. The sensor(s) 530 may communicate with one or more other devices of environment 500, as described elsewhere herein.

The user device 540 may include one or more devices capable of receiving, generating, storing, processing, and/or providing information associated with digital twin predictions, as described elsewhere herein. The user device 540 may include a communication device and/or a computing device. For example, the user device 540 may include a wireless communication device, a mobile phone, a user equipment, a laptop computer, a tablet computer, a desktop computer, a gaming console, a set-top box, a wearable communication device (e.g., a smart wristwatch, a pair of smart eyeglasses, a head mounted display, or a virtual reality headset), or a similar type of device. The user device 540 may communicate with one or more other devices of environment 500, as described elsewhere herein.

The event database 550 may include one or more devices capable of receiving, generating, storing, processing, and/or providing information associated with digital twin events, as described elsewhere herein. The event database 550 may include a communication device and/or a computing device. For example, the event database 550 may include a database, a server, a database server, an application server, a client server, a web server, a host server, a proxy server, a virtual server (e.g., executing on computing hardware), a server in a cloud computing system, a device that includes computing hardware used in a cloud computing environment, or a similar type of device. The event database 550 may communicate with one or more other devices of environment 500, as described elsewhere herein.

The model database 560 may include one or more devices capable of receiving, generating, storing, processing, and/or providing information associated with digital twin models, as described elsewhere herein. The model database 560 may include a communication device and/or a computing device. For example, the model database 560 may include a database, a server, a database server, an application server, a client server, a web server, a host server, a proxy server, a virtual server (e.g., executing on computing hardware), a server in a cloud computing system, a device that includes computing hardware used in a cloud computing environment, or a similar type of device. The model database 560 may communicate with one or more other devices of environment 500, as described elsewhere herein.

The number and arrangement of devices and networks shown in FIG. 5 are provided as an example. In practice, there may be additional devices and/or networks, fewer devices and/or networks, different devices and/or networks, or differently arranged devices and/or networks than those shown in FIG. 5. Furthermore, two or more devices shown in FIG. 5 may be implemented within a single device, or a single device shown in FIG. 5 may be implemented as multiple, distributed devices. Additionally, or alternatively, a set of devices (e.g., one or more devices) of environment 500 may perform one or more functions described as being performed by another set of devices of environment 500.

FIG. 6 is a diagram of example components of a device 600 associated with event processing and prediction updating at a digital twin. Device 600 may correspond to a user device, an event database, a model database, and/or a sensor. In some implementations, a user device, an event database, a model database, and/or a sensor may include one or more devices 600 and/or one or more components of device 600. As shown in FIG. 6, device 600 may include a bus 610, a processor 620, a memory 630, an input component 640, an output component 650, and a communication component 660.

Bus 610 may include one or more components that enable wired and/or wireless communication among the components of device 600. Bus 610 may couple together two or more components of FIG. 6, such as via operative coupling, communicative coupling, electronic coupling, and/or electric coupling. Processor 620 may include a central processing unit, a graphics processing unit, a microprocessor, a controller, a microcontroller, a digital signal processor, a field-programmable gate array, an application-specific integrated circuit, and/or another type of processing component. Processor 620 is implemented in hardware, firmware, or a combination of hardware and software. In some implementations, processor 620 may include one or more processors capable of being programmed to perform one or more operations or processes described elsewhere herein.

Memory 630 may include volatile and/or nonvolatile memory. For example, memory 630 may include random access memory (RAM), read only memory (ROM), a hard disk drive, and/or another type of memory (e.g., a flash memory, a magnetic memory, and/or an optical memory). Memory 630 may include internal memory (e.g., RAM, ROM, or a hard disk drive) and/or removable memory (e.g., removable via a universal serial bus connection). Memory 630 may be a non-transitory computer-readable medium. Memory 630 stores information, instructions, and/or software (e.g., one or more software applications) related to the operation of device 600. In some implementations, memory 630 may include one or more memories that are coupled to one or more processors (e.g., processor 620), such as via bus 610.

Input component 640 enables device 600 to receive input, such as user input and/or sensed input. For example, input component 640 may include a touch screen, a keyboard, a keypad, a mouse, a button, a microphone, a switch, a sensor, a global positioning system sensor, an accelerometer, a gyroscope, and/or an actuator. Output component 650 enables device 600 to provide output, such as via a display, a speaker, and/or a light-emitting diode. Communication component 660 enables device 600 to communicate with other devices via a wired connection and/or a wireless connection. For example, communication component 660 may include a receiver, a transmitter, a transceiver, a modem, a network interface card, and/or an antenna.

Device 600 may perform one or more operations or processes described herein. For example, a non-transitory computer-readable medium (e.g., memory 630) may store a set of instructions (e.g., one or more instructions or code) for execution by processor 620. Processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry is used instead of or in combination with the instructions to perform one or more operations or processes described herein. Additionally, or alternatively, processor 620 may be configured to perform one or more operations or processes described herein. Thus, implementations described herein are not limited to any specific combination of hardware circuitry and software.

The number and arrangement of components shown in FIG. 6 are provided as an example. Device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

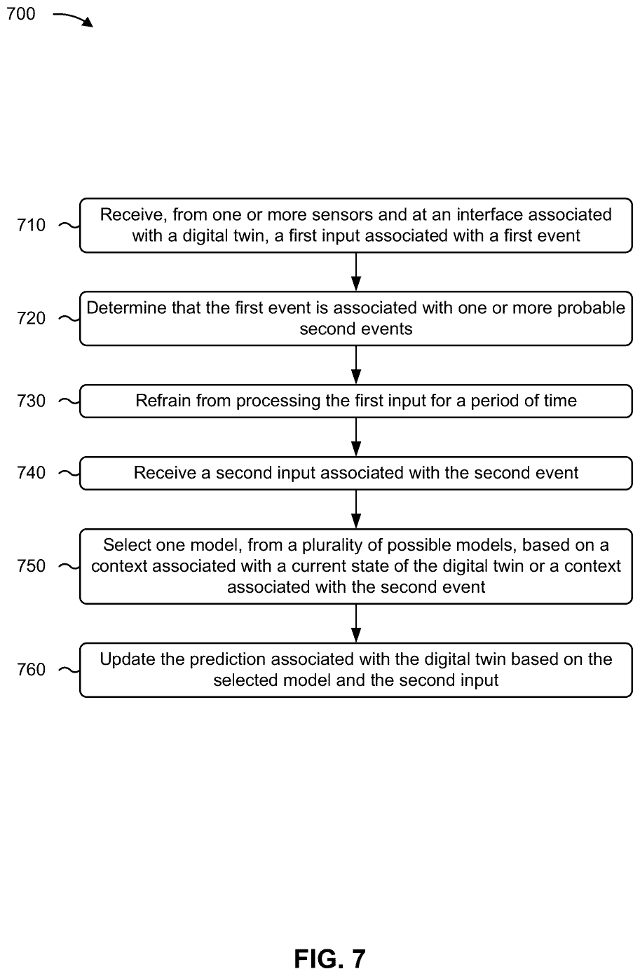

FIG. 7 is a flowchart of an example process 700 associated with event processing and prediction updating at a digital twin. In some implementations, one or more process blocks of FIG. 7 are performed by a device (e.g., digital twin host 501). In some implementations, one or more process blocks of FIG. 7 are performed by another device or a group of devices separate from or including the device, such as one or more sensors (e.g., sensor(s) 530), a user device (e.g., user device 540), an event database (e.g., event database 550), and/or a model database (e.g., model database 560). Additionally, or alternatively, one or more process blocks of FIG. 7 may be performed by one or more components of device 600, such as processor 620, memory 630, input component 640, output component 650, and/or communication component 660.

As shown in FIG. 7, process 700 may include receiving, from one or more sensors and at an interface associated with a digital twin, a first input associated with a first event (block 710). For example, the digital twin host may receive, from one or more sensors and at an interface associated with a digital twin, a first input associated with a first event, as described herein.

As further shown in FIG. 7, process 700 may include determining that the first event is associated with a probable second event (block 720). For example, the digital twin host may determine that the first event is associated with a probable second event, as described herein.

As further shown in FIG. 7, process 700 may include refraining from processing the first input for a period of time (block 730). For example, the digital twin host may refrain from processing the first input for a period of time, as described herein.

As further shown in FIG. 7, process 700 may include receiving a second input associated with the probable second event (block 740). For example, the digital twin host may receive a second input associated with the probable second event, as described herein.

As further shown in FIG. 7, process 700 may include selecting a model, from a plurality of possible models, based on a context associated with a current state of the digital twin or a context associated with the probable second event (block 750). For example, the digital twin host may select a model, from a plurality of possible models, based on a context associated with a current state of the digital twin or a context associated with the probable second event, as described herein.

As further shown in FIG. 7, process 700 may include updating a prediction associated with the digital twin based on the selected model and the second input (block 760). For example, the digital twin host may update a prediction associated with the digital twin based on the selected model and the second input, as described herein.

Process 700 may include additional implementations, such as any single implementation or any combination of implementations described below and/or in connection with one or more other processes described elsewhere herein.

In a first implementation, process 700 includes transmitting, to a user device, a visualization associated with the updated prediction.

In a second implementation, alone or in combination with the first implementation, process 700 includes receiving, from a storage associated with events, a data structure indicating a hierarchy of event types, and determining, based on the hierarchy of event types, the one or more probable second events.

In a third implementation, alone or in combination with one or more of the first and second implementations, process 700 includes inputting, to a machine learning model, the first input, and receiving, from the machine learning model, output indicating the one or more probable second events.

In a fourth implementation, alone or in combination with one or more of the first through third implementations, process 700 includes filtering the first input in order to generate the updated prediction based on the second input.

In a fifth implementation, alone or in combination with one or more of the first through fourth implementations, process 700 includes calculating a corresponding cost and a corresponding error for each model of the plurality of possible models, and selecting the model based on the corresponding cost and the corresponding error for the model.

In a sixth implementation, alone or in combination with one or more of the first through fifth implementations, the context associated with the current state of the digital twin comprises a location associated with the digital twin, a time associated with the digital twin, or a current function associated with the digital twin.

In a seventh implementation, alone or in combination with one or more of the first through sixth implementations, the context associated with the probable second event comprises a location associated with the probable second event, a time associated with the probable second event, or a current function associated with the probable second event.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

The foregoing disclosure provides illustration and description, but is not intended to be exhaustive or to limit the implementations to the precise forms disclosed. Modifications may be made in light of the above disclosure or may be acquired from practice of the implementations.

As used herein, the term “component” is intended to be broadly construed as hardware, firmware, or a combination of hardware and software. It will be apparent that systems and/or methods described herein may be implemented in different forms of hardware, firmware, and/or a combination of hardware and software. The actual specialized control hardware or software code used to implement these systems and/or methods is not limiting of the implementations. Thus, the operation and behavior of the systems and/or methods are described herein without reference to specific software code—it being understood that software and hardware can be used to implement the systems and/or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A method, comprising:
receiving, from one or more sensors and at an interface associated with a digital twin, a first input associated with a first event;
determining that the first event is associated with one or more probable second events;
refraining from processing the first input for a period of time; and
updating a prediction associated with the digital twin using the first input based on expiry of the period of time, or updating a prediction associated with the digital twin using second input associated with the one or more probable second events based on receiving the second input.

2. The method of claim 1, further comprising:
transmitting, to a user device, a visualization associated with the updated prediction.

3. The method of claim 1, wherein determining that the first event is associated with one or more probable second events comprises:
receiving, from a storage associated with events, a data structure indicating a hierarchy of event types; and
determining, based on the hierarchy of event types, the one or more probable second events.

4. The method of claim 3, wherein the data structure further indicates the period of time.

5. The method of claim 1, wherein determining that the first event is associated with the one or more probable second events comprises:
inputting, to a machine learning model, the first input; and
receiving, from the machine learning model, output indicating the one or more probable second events.

6. The method of claim 1, further comprising:
filtering the first input in order to generate the updated prediction based on the second input.

7. A device, comprising:
one or more memories; and
one or more processors, communicatively coupled to the one or more memories, configured to:
receive, from one or more sensors and at an interface associated with a digital twin, input associated with a new event;
determine that the event triggers an update for a prediction associated with the digital twin;
select a model, from a plurality of possible models, based on a context associated with a current state of the digital twin or a context associated with the event; and
update the prediction associated with the digital twin based on the selected model and the input.

8. The device of claim 7, wherein the one or more processors are further configured to:
transmit, to a user device, a visualization associated with the updated prediction.

9. The device of claim 7, wherein the one or more processors, to select the model, are configured to:
calculate a corresponding cost and a corresponding error for each model of the plurality of possible models; and
select the model based on the corresponding cost and the corresponding error for the model.

10. The device of claim 7, wherein the context associated with the current state of the digital twin comprises a location associated with the digital twin, a time associated with the digital twin, or a current function associated with the digital twin.

11. The device of claim 7, wherein the context associated with the event comprises a location associated with the event, a time associated with the event, or a current function associated with the event.

12. The device of claim 7, wherein the one or more processors are further configured to:
receive one or more additional inputs based on the selected model.

13. A non-transitory computer-readable medium storing a set of instructions, the set of instructions comprising:
one or more instructions that, when executed by one or more processors of a device, cause the device to:
receive, from one or more sensors and at an interface associated with a digital twin, a first input associated with a first event;
determine that the first event is associated with a probable second event;
refrain from processing the first input for a period of time;
receive a second input associated with the probable second event;
select a model, from a plurality of possible models, based on a context associated with a current state of the digital twin or a context associated with the probable second event; and
update a prediction associated with the digital twin based on the selected model and the second input.

14. The non-transitory computer-readable medium of claim 13, wherein the one or more instructions, when executed by the one or more processors, further cause the device to:
transmit, to a user device, a visualization associated with the updated prediction.

15. The non-transitory computer-readable medium of claim 13, wherein the one or more instructions, that cause the device to determine that the first event is associated with a probable second event, cause the device to:
receive, from a storage associated with events, a data structure indicating a hierarchy of event types; and
determine, based on the hierarchy of event types, the one or more probable second events.

16. The non-transitory computer-readable medium of claim 13, wherein the one or more instructions, that cause the device to determine that the first event is associated with a probable second event, cause the device to:
input, to a machine learning model, the first input; and
receive, from the machine learning model, output indicating the one or more probable second events.

17. The non-transitory computer-readable medium of claim 13, wherein the one or more instructions, when executed by the one or more processors, further cause the device to:
filter the first input in order to generate the updated prediction based on the second input.

18. The non-transitory computer-readable medium of claim 13, wherein the one or more instructions, that cause the device to select the model, cause the device to:
calculate a corresponding cost and a corresponding error for each model of the plurality of possible models; and
select the model based on the corresponding cost and the corresponding error for the model.

19. The non-transitory computer-readable medium of claim 13, wherein the context associated with the current state of the digital twin comprises a location associated with the digital twin, a time associated with the digital twin, or a current function associated with the digital twin.

20. The non-transitory computer-readable medium of claim 13, wherein the context associated with the probable second event comprises a location associated with the probable second event, a time associated with the probable second event, or a current function associated with the probable second event.
